(19) United States
(12) Patent Application Publication
(10) Pub. No.: US 2009/0251227 A1
(43) Pub. Date: Oct. 8, 2009

(54) CONSTANT GM OSCILLATOR

(76) Inventor: Hrvoje (Hery) Jasa, Cumberland, ME (US)

Correspondence Address: CESARI AND MCKENNA, LLP, 88 BLACK FALCON AVENUE, BOSTON, MA, 02210, US

(21) Appl. No.: 12/196,354

(22) Filed: Aug. 22, 2008

Related U.S. Application Data
(60) Provisional application No. 61/042,050, filed on Apr. 3, 2008.

(51) Int. Cl. H03B 5/04

(52) U.S. Cl. 331/113 R; 331/66

(57) ABSTRACT

The present invention provides a constant gm circuit that generates a bias current for a emitter/source-coupled multivibrator oscillator. The stable gm bias limits the temperature dependence of the oscillator. Trimming a resistor in the constant gm circuit compensates for process variations, and current sources may be provided that are mirrors of the bias current that are also substantially independent of the supply voltage. The present invention provides an oscillator with less that 1% frequency changes due to PVT variations.

### RELATED APPLICATIONS

This application is related to and claims the benefit of the filing of Provisional Application Ser. No. 61/042,050, filed Apr. 3, 2008; this provisional application is of common title, ownership and inventorship. The provisional application is incorporated herein by reference.

### BACKGROUND OF THE INVENTION

1. Field of the Invention

The present invention is related to oscillators and more particularly source-coupled oscillators that are relatively immune to manufacturing process (process), voltage (the circuit power source) and temperature, or PVT, variations.

2. Background Information

FIG. 1 illustrates a known source coupled astable multi-vibrator or oscillator. This architecture, however, is subject to frequency changes due to temperature, voltage and process variations.

FIG. 1 has two equal load resistors, R and R′, and the FET's, M1 and M2, are source coupled through a floating capacitor C. The circuit includes two independent current sources Io, Io′, and Ic represents the charging/discharging current through C. If Io and Io′ are equal the output clock (say from one of the drains) duty cycle will be near 50%.

This circuit has been analyzed in a paper, Analysis of Emitter (Source)-Coupled Multivibrators; Buonomo, Antonia; LoSchiavo, Alessandro, in the IEEE Transactions on Circuit and Systems—Regular Papers, Vol. 53, June 2006. This paper is incorporated herein by reference. The frequency of oscillation, as derived in the paper, was found to be:

$$f = \frac{{g}_{m}}{2 C [ 2 ( {Rg}_{m} - 1 ) ln ( \frac{{I}_{c}}{{I}_{o}} ) - \frac{3}{8 {I}_{o}^{2}} ( {I}_{c}^{2} - {I}_{i}^{2} ) - \frac{35}{256 {I}_{o}^{4}} ( {I}_{c}^{4} - {I}_{i}^{4} ) ]} \\ Where {g}_{m} = 2 \sqrt{{kI}_{o}} \qquad Eq . 1$$

Iₒ,Iᵢ,I_{c} are currents the authors defined and used in the derivation of Eq. 1, where they help determine how the charge is distributed in the circuit. Once the other components are selected, however, these currents themselves are, at least to a first order, independent.

Io represents a bias current, that correlates to Io and Io′ in FIG. 1. As shown above, Io does affect gₘ.

From Eq. 1 it can be seen that the oscillation frequency is largely controlled by four major parameters: the timing capacitor C, the load resistors R, the bias current Iₒ and the gₘ of the devices.

The transconductance, gₘ, is defined as the ratio of an output current to an input voltage, and applies to transistors M1 and M2 of FIG. 1.

From Eq. 1, it is clear that the above four major parameters will vary as temperature changes, likely as supply voltage changes, and as components are made under with different processes. These different processes refer generally to fabrication processes where slightly faster or slower devices may be made using the same process steps at different times and at the same or different foundries. Of course, if a different CMOS process is used, the same principles of physics will apply.

Since the frequency of emitter/source coupled oscillators will be affected by PVT variations, and that it would be advantageous to minimize these effects.

### SUMMARY OF THE INVENTION

The PVT effects on source coupled oscillators may be reduced by controlling the above four major parameters. The present invention provides for replacing the drain resistors of FIG. 1 with active components, and replacing the current sources of FIG. 1 with voltage independent controlled current sources. Illustratively, the replacement active components and current sources will be, to a first order, functions of gₘ.

Illustratively, the present invention provides cross coupled transistors with a timing capacitor arranged between the sources or the emitters of the cross coupled transistors. Transistor current sources supply bias currents to the cross coupled transistors, and load transistors are located in the drains or collectors to receive the bias currents via the cross coupled transistors. A constant gm circuit is arranged to supply the bias currents. All the transistors exhibit a constant gm due to the bias current from the constant gm circuit.

With respect to FIG. 1, for example, the resistors may be replaced by diode connected transistors where their resistances are characterized by 1/gₘ as are the cross coupled transistors. The current sources, Io and Io′ may be implemented by transistor that will have a fixed gₘ to provide a fixed current. And if the gₘ's are made near constant over process and temperature (PT) variations, the effects on the oscillator's frequency are diminished. At the same time the bias current, Io and Io′, may be made largely independent of the supply voltage. In this embodiment, only the C parameter will remain as the only one of the four major parameters affecting the PVT frequency dependence of the source coupled oscillator frequency.

The present invention provides a constant gₘ circuit, from which a current may be drawn to bias all the active components of the source couple oscillator at a gₘ that is constant over PVT variations. And the oscillator frequency (Eq. 1)will be correspondingly constant over the PVT variations.

It will be appreciated by those skilled in the art that although the following Detailed Description will proceed with reference being made to illustrative embodiments, the drawings, and methods of use, the present invention is not intended to be limited to these embodiments and methods of use. Rather, the present invention is of broad scope and is intended to be defined as only set forth in the accompanying claims.

### BRIEF DESCRIPTION OF THE DRAWINGS

The invention description below refers to the accompanying drawings, of which:

FIG. 1 is circuit schematic of a prior art source coupled oscillator;

FIG. 2 is circuit schematic of an adaptation of FIG. 1;

FIG. 3 is a chart of process and temperature variations of frequency of the circuit of FIG. 2;

FIG. 4 is a schematic of a constant gm circuit;

FIG. 5 is a more detailed version of the circuit in FIG. 4; and

FIG. 6 is a chart of process and temperature variations of frequency on an circuit embodying the present invention.

### DETAILED DESCRIPTION OF AN ILLUSTRATIVE EMBODIMENT

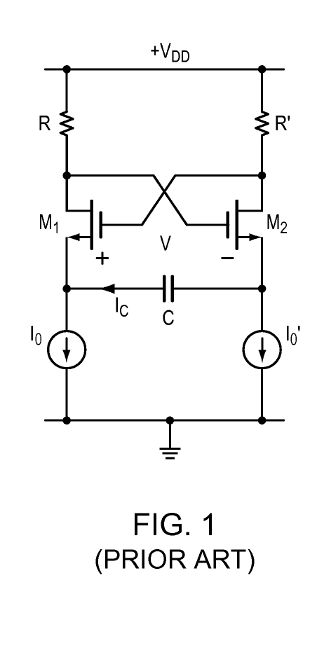

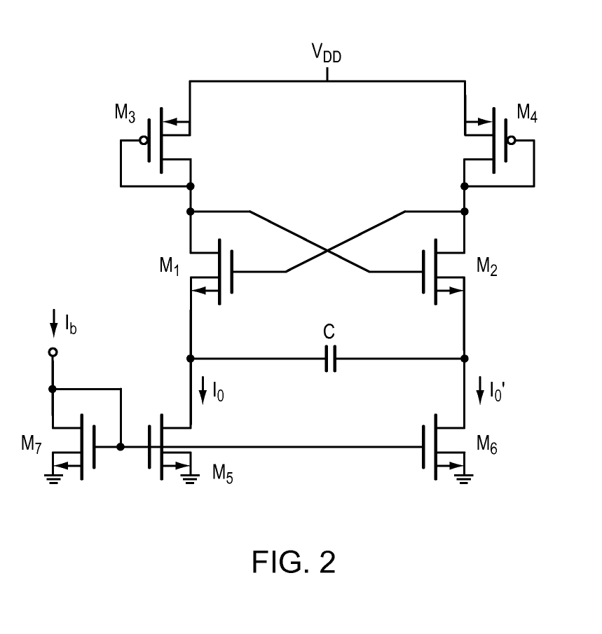

FIG. 2 is a schematic of a source coupled oscillator core. It is an adaptation of FIG. 1 where the drain resistors, R, and R′, are replaced by diode connected FETs, M3 and M4, respectively. The effective resistance of the diode connected M3 and M4 are related to 1/gₘ. And the current sources, Io and Io′ are replaced by current mirrors M5 and M6, where the drain currents Io and Io′ are mirrors of Ib sourced from a constant gₘ circuit and is designed to be independent of Vdd. With these changes, the PVT effects of the resistors and the current sources are lumped with the PVT effects of the gₘ. In such an instance, the gₘ is made constant reducing the PVT effects on the oscillator frequency.

Although FIGS. 1 and 2 use MOSFETs, these circuit may be constructed with bipolar or hybrid transistors.

In FIG. 2 the currents Io and Io′ are set by current Ib injected into the cell via M7. Cross coupled pair M1 and M2 are isolated well transistors that eliminates the back gate bias of these transistors.

When, gₘ is made constant, as mentioned above, the PVT effects on the oscillator frequency of the circuit of FIG. 2 will primarily depend only on the capacitor. The PVT effects of R, Io and gₘ are, to a first order, reduced.

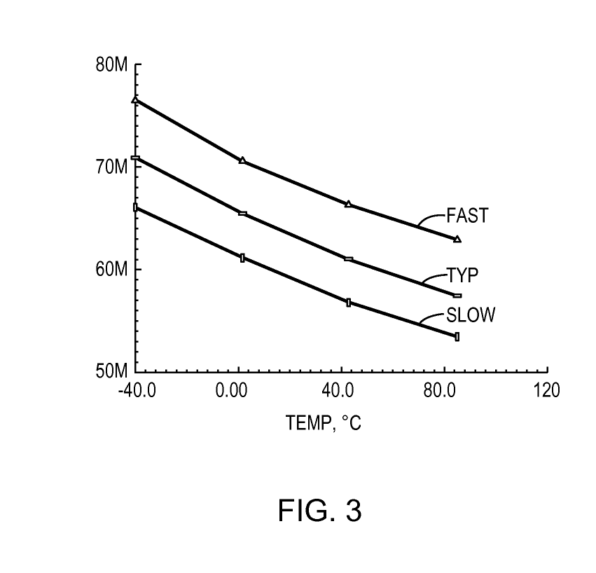

FIG. 3 is a chart of the PVT sensitivity of the circuit of FIG. 2, but where Ib is a constant. For example, Ib may be generated by a bandgap reference (known to those skilled in the art), where Ib remains constant over the PVT parameters. A SLOW (58 mHz), a TYP (63 mHz) and a FAST (68 mHz) oscillator frequency illustrate process and temperature variations on oscillator core frequency.

From FIG. 3 the range of frequency generated by the oscillator core is −17.7%<f^{osc}<18%. This is a large range. Observe that even if post process trimming were applied, the temperature portion of the sensitivity is −11.1%<f_{osc(temp)}<+10.2%.

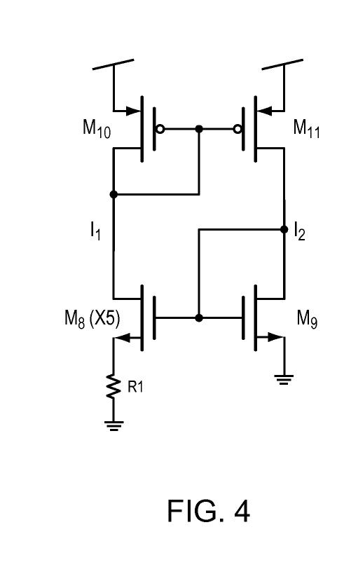

### Constant Gm Bias FIG. 4;

As mentioned above, if the FIG. 2 circuit is biased to have a constant gₘ for all the transistors, the gₘ portion of the variance of Eq. 1 is substantially eliminated. And if the loads resistors R and R′ are replaced with diode connected MOS devices, the load devices will have an equivalent resistance proportional to 1/gₘ. This eliminates the R and the gₘ factors from the above four major factors affecting the frequency from Eq. 1. Also, eliminating the voltage dependence of the current sources will eliminate the third factor, V, with only the capacitance remaining.

The constant gₘ bias is produced with the circuit structure shown in FIG. 4. Assuming I1 equal I2, as they are mirrors via M10 and M11, I=I₁=I₂, and if the devices are all biased in strong inversion, the following apply:

$${I}_{1} = M \frac{β}{2} {( {V}_{gs} - {I}_{1} R - {V}_{t} )}^{2} \\ {I}_{2} = \frac{β}{2} {( {V}_{gs} - {V}_{t} )}^{2} \\ Solving gives \text{:} I = \frac{2}{β {R}^{2}} {( 1 - \frac{1}{\sqrt{M}} )}^{2} . \qquad Eq . 2$$

Eq. 2 illustrates that the only dependence of the current is to resistor R (of FIG. 4 and Eq. 2) and physical transistor parameters Vₜ and β=μCₒₓW/L. Where Vt is the threshold voltage, t carrier mobility, W is the width and L the length of the transistor channel, and Cox is the gate oxide capacitance. The M of Eq. 2 is a multiplier that is a function of the sizes of the transistors involved. In one example, of FIG. 4, M8 is five times larger than M9 thus, M equals five.

The gₘ of a transistor is defined with the following equations:

$${I}_{D} = \frac{β}{2} {( {V}_{gs} - {V}_{t} )}^{2} ⇒ gm = \sqrt{2 β {I}_{D}} . \qquad Eq . 3$$

The arrow in Eq. 3 refers to the equation for ID “leading” to the equation for gₘ.

Substituting Eq. 3 into Eq. 2:

$$gm = \sqrt{2 β {I}_{D}} = \sqrt{2 β \frac{2}{β {R}^{2}} {( 1 - \frac{1}{\sqrt{M}} )}^{2}} = \frac{2}{R} ( 1 - \frac{1}{\sqrt{M}} ) . \qquad Eq . 4$$

Illustratively, the current generated by the FIG. 4 circuit is used as the bias current for all transistors in the circuit of FIG. 2. Since the current generated in the FIG. 4 circuit relates to a gₘ that is only a function of R1 and M. This current is used as Ib in FIG. 2, and as the source of Io and Io′ via the current mirrors M7, M5 and M6. Since all the transistors will have this same bias current and thus a constant gₘ. Moreover, since gₘ is only a function of R1 and M, it can be set. The point is that the ratios of the gₘs remain constant and track each other over PVT variations. Also, the current sources may be designed as power supply independent.

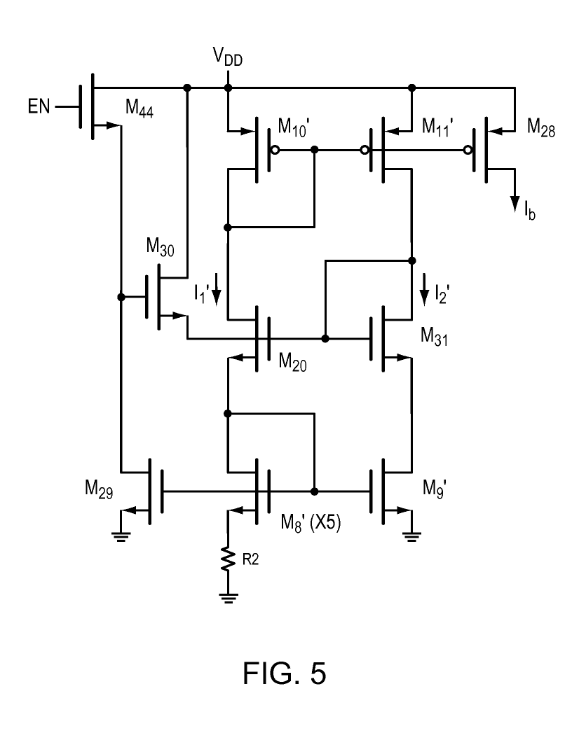

FIG. 5 is a more detailed circuit illustration of the FIG. 4 circuit. In FIG. 5, M8′, M9′, M10′ and M11′ represent M8, M9, M10 and M11 of FIG. 4. Ib from the drain of M28 is a mirror of I₂′ and I₁′.

An enable signal, EN, when high enables the constant gₘ circuit of FIG. 5 to provide the Ib. As known to those skilled in the art, many different enable-type configurations may be used to advantage. In any event, a turned on M44 turns on M30 that drives the gates of M20 and M31. M8′ and M9′ are on and the voltage across R2 sets the currents I₁, I₂, Ib and the drain currents of M29 and M44. The feedback arrangement of M8′, M29 M30 and M20 stabilizes the current I1′ and the mirror currents. Illustratively, M8′ is made five times larger than M9′, thereby M equals five. Eqs. 3 and 4 apply, so that gₘ depends only on R2 and M.

In practice, R2 may be and external resistor that is trimmed to compensate for process variations.

### Temperature Independence

From Eq. 1, R can be replaced by 1/gₘ due to the diode connected transistors giving the frequency response:

$$f = \frac{{g}_{m}}{2 C [ 2 ( \frac{{g}_{m}}{{g}_{mR}} - 1 ) ln ( \frac{{I}_{c}}{{I}_{o}} ) - \frac{3}{8 {I}_{o}^{2}} ( {I}_{c}^{2} - {I}_{i}^{2} ) - \frac{35}{256 {I}_{o}^{4}} ( {I}_{c}^{4} - {I}_{i}^{4} ) ]} . \qquad Eq . 5$$

The frequency is stabilized by stabilizing gₘ, This is accomplished with the constant gₘ circuit of FIG. 5.

As mentioned above, the drain current from M28 is Ib in FIG. 2, and this current corresponds to a constant gₘ as discussed for FIGS. 4 and 5, and is used to bias the active components of the oscillator circuit of FIG. 2. Ib feeds the oscillator current mirror M7 and its mirrors M5 and M6 to produce Io and Io′ that feed M1/M3 and M2/M4, respectively. And with this connection, the gₘ is constant for each transistor (set by R2 and M of FIG. 5) and is independent of temperature and voltage variations of the oscillator core. And as mentioned above, R2 may be trimmed to compensate for process variations. The result is a circuit where the frequency is largely independent of PVT variations and depends primarily only on the timing capacitor C.

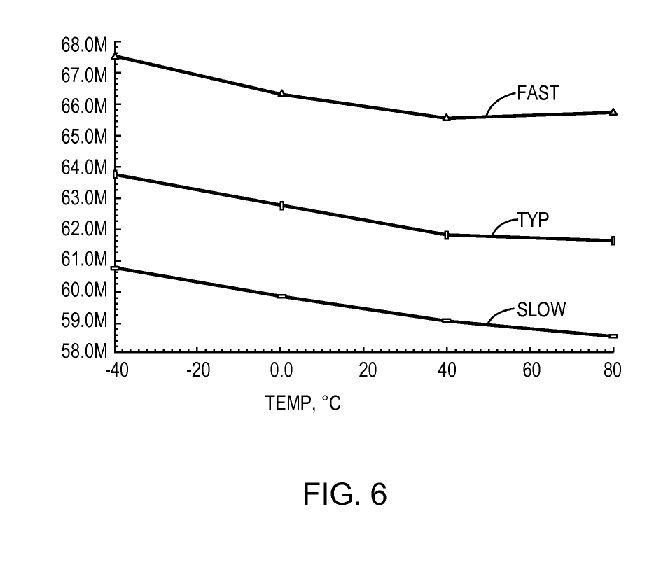

FIG. 6 contains temperature and process charts that depicts the robustness of the circuit combining FIG. 5 and FIG. 2 versus process and environment. The total range is −4.4%<f_{osc}<6.6%. Observe that the temperature range has been reduced to ±1%, this is a ten fold improvement in the original design as illustrated in FIG. 3 where a constant current fed M7 rather than the constant gₘ current from M28 of FIG. 5.

It should be understood that above-described embodiments are being presented herein as examples and that many variations and alternatives thereof are possible. Accordingly, the present invention should be viewed broadly as being defined only as set forth in the hereinafter appended claims.

What is claimed is:

1. An oscillator comprising:
cross coupled transistors;
a timing capacitor arranged between the cross coupled transistors;
transistor current sources arranged to supply bias current to the cross coupled transistors;
load transistors arranged to receive the currents via the cross coupled transistors, wherein the cross coupled transistors, the transistor current sources and the load transistors all share the bias currents, and
a constant gm circuit that supplies the bias current.

2. A source coupled oscillator comprising:
cross coupled MOSFETs, having drains, gates and sources, and with their drains connected to the other's gates;
a timing capacitor connected between the two sources;
diode connected transistors, one configured from each drain of the cross coupled transistor to a power supply;
current sources configured between each source and ground, wherein the current sources supply currents that are arranged so that the gm's of each of the cross coupled and diode connected transistors are constant with variations of temperature and the fabricating process used to make the oscillator.

3. The source coupled oscillator of claim 2 further comprising:
a bias current, wherein the current sources are configured to be mirror currents of the bias current, so that mirror currents flows through all the MOSFETs, and wherein the gₘ of each of the cross coupled and diode connected MOS FETs have gm's that are near constant with variations of temperature and the fabricating process used to make the oscillator.

4. The source coupled oscillator of claim 2 wherein the current sources are independent of supply voltage, wherein the frequency of oscillation of the oscillator is constant over variations of temperature, fabricating processes and supply voltage.

5. The source coupled oscillator of claim 3 further comprising a constant gₘ circuit that provides a constant gₘ bias current, the constant gₘ circuit comprising:
first and second MOS FETs arranged as current mirrors,
first and second opposite polarity MOS FETs, the first configured with its drain connected to the drain of the first MOS FET and its source connected to ground, and the second with its drain connected to the drain of the second MOS FET;
a resistor with one side connected to the source of the second opposite polarity MOS FET, the other side of the resistor connected to ground; wherein the gₘ of the MOS FETs are defined by
$$gm = \sqrt{2 β {I}_{D}} = \sqrt{2 β \frac{2}{β {R}^{2}} {( 1 - \frac{1}{\sqrt{M}} )}^{2}} = \frac{2}{R} ( 1 - \frac{1}{\sqrt{M}} ) ;$$
where R is the resistor, and M is a physical size factor between the first and the second current mirrors,
a third mirror MOS FET that mirrors the current in one of the first or second MOS FET current mirrors, wherein the current in the third current mirror is a constant gₘ mirror current.

6. The source coupled oscillator of claim 5 further comprising:
a third MOS FET with its source driving the gates of both opposite polarity MOS FETs, and its gate and drain connected to a positive voltage source, wherein the voltage across the resistor is set, and wherein the currents in the first, second and third current mirrors are set.

7. The source coupled oscillator of claim 1 wherein the MOS FETs are replaced by transistors selected from the group consisting of FETS, bipolar and hybrid transistors.

8. A process for making a source coupled oscillator comprising the steps of:
cross coupling MOS FETs, having their drains connected to the other's gates;
connecting a a timing capacitor between the two sources;
configuring diode connected MOS FETs between each drain of the cross coupled MOS FETs to a power supply;
configuring current sources between each source and ground, wherein the current sources supply currents that are arranged so that the gm's of each of the cross coupled and diode connected MOS FETs are constant with variations of temperature and the fabricating process used to make the oscillator.

9. The process of claim 8 further comprising the steps of:
mirroring the current sources from a bias current, wherein mirrors of the bias current flow through all the MOSFETs, and wherein the gm of all the MOS FETs are near constant with variations of temperature and the fabricating process used to make the oscillator.

10. The process of claim 8 further comprising the steps of configuring the current sources to be independent of supply voltage, wherein the frequency of oscillation of the oscillator is constant over variations of temperature, fabricating processes and supply voltage.

11. The process of claim 9 further comprising the steps of:
generating the bias current from a constant gₘ circuit; that provides a constant gₘ bias current, the constant gₘ circuit comprising:
configuring a first and second MOS FETs as current mirrors,
receiving the currents from the current mirrors by the drains of first and second opposite polarity MOS FETs,
directing one of the received mirror currents from the first opposite polarity MOS FET to a resistor; wherein
defining the gₘ of the MOS FETs by
$$gm = \sqrt{2 β {I}_{D}} = \sqrt{2 β \frac{2}{β {R}^{2}} {( 1 - \frac{1}{\sqrt{M}} )}^{2}} = \frac{2}{R} ( 1 - \frac{1}{\sqrt{M}} ) ;$$
where R is the resistor, and M is a physical size factor between the first and the second current mirrors,
mirroring the current, in one of the first or second MOS FET current mirrors, wherein this mirror current is a constant gₘ mirror current.

12. The process of claim 11 further comprising the steps of:
driving the gates of both opposite polarity MOS FETs from a positive voltage source,
setting the voltage across the resistor via the positive voltage source, wherein setting the voltage across the resistor sets all the mirrored currents.

13. The process of claim 8 wherein the transistors are selected from the group consisting of FETs, bipolar and hybrid transistors.

14. A process for generating a oscillation comprising the steps of:
cross coupling transistors;
positioning a timing capacitor arranged between the cross coupled transistors;
supplying a bias currents to the cross coupled transistors via transistor current sources;
loading the cross couple transistors with additional transistors arranged to receive the bias currents, wherein the cross coupled transistors, the transistor current sources and the load transistors all share the bias currents, and
making the bias current from a constant gm circuit.
